(19) United States
(12) Patent Application Publication
(10) Pub. No.: US 2015/0028108 A1
(43) Pub. Date: Jan. 29, 2015

(54) DOUBLE LOOP INDUCTOR RFID

(71) Applicant: Alien Technology Corporation, Morgan Hill, CA (US)

(72) Inventor: John Stephen Smith, San Jose, CA (US)

(21) Appl. No.: 14/339,194

(22) Filed: Jul. 23, 2014

Related U.S. Application Data
(60) Provisional application No. 61/858,074, filed on Jul. 24, 2013.

(51) Int. Cl. G06K 19/077; H01L 49/02

(52) U.S. Cl. CPC G06K 19/07754; G06K 19/07783; H01L 28/10
USPC 235/492; 438/381

(57) ABSTRACT

An apparatus and method for coupling a radio frequency identification (RFID) integrated circuit (IC) with a dual loop coil formed on a lead frame. In one embodiment, the lead frame is encapsulated in an IC package.

This application is related to co-pending U.S. Provisional Patent Application No. 61/858,074, which was filed on Jul. 24, 2013; this application claims the benefit of the provisional's filing date under 35 U.S.C. §119(e) and is hereby incorporated herein by reference in its entirety.

### FIELD OF THE INVENTION

The present invention relates to radio frequency identification (RFID) integrated circuit (IC), and more particularly methods and apparatuses for coupling a dual loop inductor to an RFID IC.

### BACKGROUND INFORMATION

RFID transponders (commonly referred to herein as “tags”) in the form of labels, inlays, straps or other forms are widely used to associate an object with an identification code. Tags generally include one or more antennas with analog and/or digital electronic circuits that include communications electronics (such as an RF transceiver), data memory (for storing one or more identification codes), processing logic (such as a microcontroller) and one or more state storage devices. Examples of applications that can use RFID tags include luggage tracking, inventory control or tracking (such as in a warehouse), parcel tracking, access control to buildings or vehicles, etc.

There are three basic types of RFID tags. A passive tag is a beam powered device which rectifies energy required for operation from radio waves generated by a reader. For communication, the passive tag creates a change in reflectivity of the field which is reflected to and read by the reader. This is commonly referred to as continuous wave backscattering. A battery-powered semi-passive tag also receives and reflects radio waves from the reader; however a battery powers the tag independent of receiving power from the reader. An active tag, having an independent power supply, includes its own radio frequency source for transmission.

The reader, sometimes referred to as an interrogator, includes a transmitter to transmit RF signals to the tag and a receiver to receive tag modulated information. The transmitter and receiver can be combined as a transceiver which can use one or more antennas.

RFID tags are often manufactured by integrating their electronic components into a single RFID integrated circuit (IC). The same is typically done for RFID readers. These RFID ICs typically include at least one contact terminal which allows the RFID IC to connect to other external components such as an antenna. U.S. Pat. No. 8,201,748 describes an example of an RFID IC.

The RFID IC contact terminals are capacitive and matching circuits are often necessary to compensate for the capacitance of these terminals. It is well known in the art that an inductive tuning element may be used for this purpose. A conductive loop is commonly employed as an inductive tuning element. Some experts in the field have used the RFID's antenna to build such a conductive loop.

It has been recognized in the field that, in some cases, it is not possible to incorporate a loop into an existing antenna, and it is necessary to attach separate inductors to the RFID IC in addition to the antenna. This, of course, results in an increase in costs and size to the RFID system as a whole.

### SUMMARY OF THE DESCRIPTION

Exemplary methods, apparatuses, and systems include a radio frequency identification (RFID) integrated circuit (IC) having four terminals for making contact with other electronic devices. The said four terminals are located on the surface of the RFID IC. A lead frame that has at least two coil segments; a first coil segment being connected to the first terminal on its first end, and connected to a second terminal on the second end; and a second coil segment being connected to the third terminal on its first end, and connected to terminal four on its second end. A resistive interconnect couples the first terminal to the third terminal and is formed within one or more layers of the RFID IC. An antenna (such as a dipole antenna) can be coupled to one or more of the terminals; for example, one element of the dipole antenna can be coupled to one terminal and another element of the dipole antenna can be coupled to another terminal.

In one embodiment, the first terminal is located at the upper left corner of the RFID IC, the second terminal is located at the upper right corner of the RFID IC, the third terminal is located at the lower right corner of the RFID IC, and the fourth terminal is located at the lower left corner of the RFID IC.

In one embodiment, the first coil segment and the second coil segments may be in the shape of a square, rectangle, or circle.

In one embodiment, the resistive interconnect which couples the first terminal to the third terminal is located below the surface of the RFID IC. In an alternative embodiment, the resistive interconnect may be located on a top interconnect layer of the RFID IC.

In one embodiment, the first coil segment and the second coil segment are configured such that a dual loop coil is formed without either coil segment overlapping the other coil segment. In an alternative embodiment, the coil segments overlap each other at least one location.

In one embodiment, the RFID IC, the lead frame, the coil segments and resistive interconnect are encapsulated in an IC package. The package may be made of ceramic, plastic, or other materials known in the art. The package type may be a dual-in-line (DIP) package, a pin grid array (PGA) package, or any package commonly known in the art.

### BRIEF DESCRIPTION OF THE DRAWINGS

The present invention is illustrated by way of example and not limitation in the figures of the accompanying drawings in which like references indicate similar elements.

FIG. 1 illustrates one embodiment of an identification system that includes an Interrogator and a plurality of RF Tags;

FIG. 2 illustrates an example of one implementation of a Tag;

FIG. 3 illustrates another example of an RF Tag;

FIG. 4A illustrates a top view of an RFID IC having four terminals.

FIG. 4B illustrates a cross section side view of the RFID IC of FIG. 4A.

FIG. 4C illustrates another cross section side view of the RFID IC of FIG. 4A.

FIG. 5 illustrates an RFID IC coupled to a rectangular dual coil loop.

FIG. 6 illustrates an RFID IC coupled to a square dual coil loop.

FIG. 7 illustrates an RFID IC coupled to a circular dual coil loop.

FIG. 8 illustrates an RFID IC coupled to a dual coil loop where coil segments overlap each other.

FIG. 9 illustrates another example of an RFID IC coupled to a dual loop coil where the coil segments overlap each other.

FIG. 10A illustrates a cross section side view of an RFID IC coupled to the coil segments via bond wires.

FIG. 10B illustrates a cross section side view of an RFID IC coupled to the coil segments by the flip chip method.

FIG. 11 illustrates a flowchart representation of coupling an RFID IC to the coil segments of a lead frame.

### DETAILED DESCRIPTION

The following description and drawings are illustrative of the invention and are not to be construed as limiting the invention. Numerous specific details are described to provide a thorough understanding of the present invention. However, in certain instances, well-known or conventional details are not described in order to avoid obscuring the description of the present invention. The term “coupled” as used herein, may mean directly coupled or indirectly coupled through one or more intervening components. References to one or an embodiment in the present disclosure are not necessarily references to the same embodiment, and such references mean at least one.

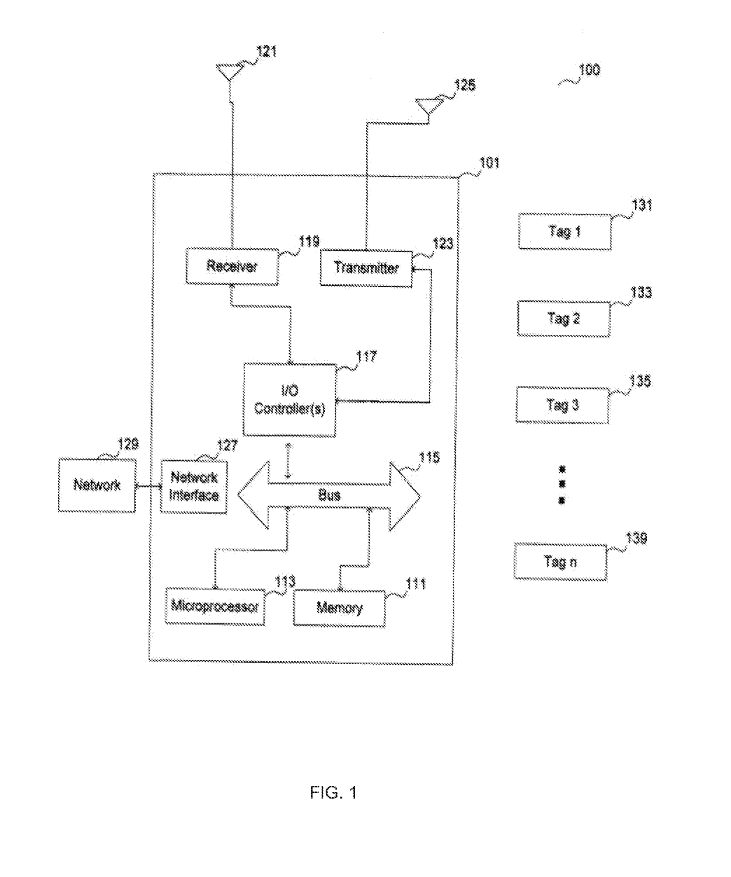

FIG. 1 illustrates an example of a Tag programming system 100 which includes the Interrogator 101 and a plurality of Tags 131, 133,135, . . . and 139. In one embodiment, the Interrogator 101 integrates a programmer and reader in one device. In one embodiment, the Tag programming system uses a reader-talks first RFID system using either passive or semi-passive active backscatter transponders as Tags. The incorporation of a battery into a Tag is an expanded feature to facilitate longer read range; however, the use of the battery does require certain trade-offs, such as higher costs, limited longevity, larger form factor, greater weight and end-of-life disposal requirements. Thus, the Tags 131-139 may have a battery or not. It will be appreciated that different types of Tags may be mixed in a system where an Interrogator is interrogating Tags with batteries and Tags without batteries. There are at least 4 classes of Tags which may be used with the present invention:

(I) no power source on the Tag except for power which is obtained from the Tag's antenna, and includes one-time programmable memory which can store the Tag's identification code and may include factory programmed memory, (II) a Tag without a power source on the Tag except for power which is obtained from the Tag's antenna, but when powered from the Interrogator, can write, erase, or rewrite data to non-volatile memory in the Tag; this type of Tag may also include one time programmable memory, and the Tag's identification code can be in any of these. (III) a Tag with a small battery to provide power to the circuitry in the Tag. Such a Tag may also include non-volatile memory as well as storing the Tag's identification code or other data, and other types of memory such as factory programmed memory and write once memory, and (IV) a Tag which can communicate with other Tags or other devices.

The Interrogator 101 typically includes a receiver 119 and a transmitter 123, each of which is coupled to an I/O (input/output) controller 117. The receiver 119 may have its own antenna 121, and the transmitter 123 may have its own antenna 125. It will be appreciated by those in the art that the transmitter 123 and the receiver 119 may share the same antenna. The receiver 119 and the transmitter 123 may be similar to conventional receiver and transmitter units found in current Interrogators. The receiver and transmitter typically operate, in North America, in a frequency range of about 900 megahertz. In other embodiments, the range is about 2400 megahertz. It will be appreciated, however, that the operation of the RFID system disclosed herein is not dependent upon the specific operating frequency. The receiver and transmitter are coupled to the I/O controller 117 that controls the receipt of data from the receiver and the transmission of data, such as commands, from the transmitter 123. The I/O controller is coupled to a bus 115 that is in turn coupled to a microprocessor 113 (or processing logic) and a memory 111. There are various different possible implementations that may be used in the Interrogator 101 for the processing system represented by elements 117, 115, 113 and 111. In one embodiment, the Interrogator 111 may include processing logic coupled to the bus 115. Processing logic can include a microcontroller, finite state machine, or logic array. In one implementation, the microprocessor 113 is a programmable microcontroller, such as an 8051 microcontroller or other well-known microcontrollers or microprocessors (e.g., an ARM microprocessor) and the memory 111 includes dynamic random access memory and a memory controller that controls the operation of the memory. Memory 111 may also include a non-volatile read only and/or re-writable memory for storing data and software programs. The memory 111 typically contains a program that controls the operation of the microprocessor 113 and also contains data used during the processing of Tags as in the interrogation of Tags. In one embodiment further described below, the memory 111 includes a computer program which causes the microprocessor 113 to send programming commands through the I/O controller to the transmitter and to receive responses from the Tags through the receiver 119 and through the I/O controller 117. The Interrogator 101 may also include a network interface 127, such as an Ethernet interface, which allows the Interrogator 101 to communicate to other processing systems through a network 129. The network interface 127 may be coupled to the bus 115 so that it can receive data, such as the list of Tags identified in an interrogation from either the microprocessor 113 or from the memory 111.

In one embodiment the Interrogator 101 implements noise cancellation using a directional coupler and reflection circuitry. The directional coupler electrically couples by a partial and predetermined amount a signal at one port out through another port. The reflection circuit provides variable attenuation and variable phase shift of the transmit signal to generate a canceling signal. The canceling signal is summed with a received signal to cancel or diminish unmodulated reflections of the transmit signal.

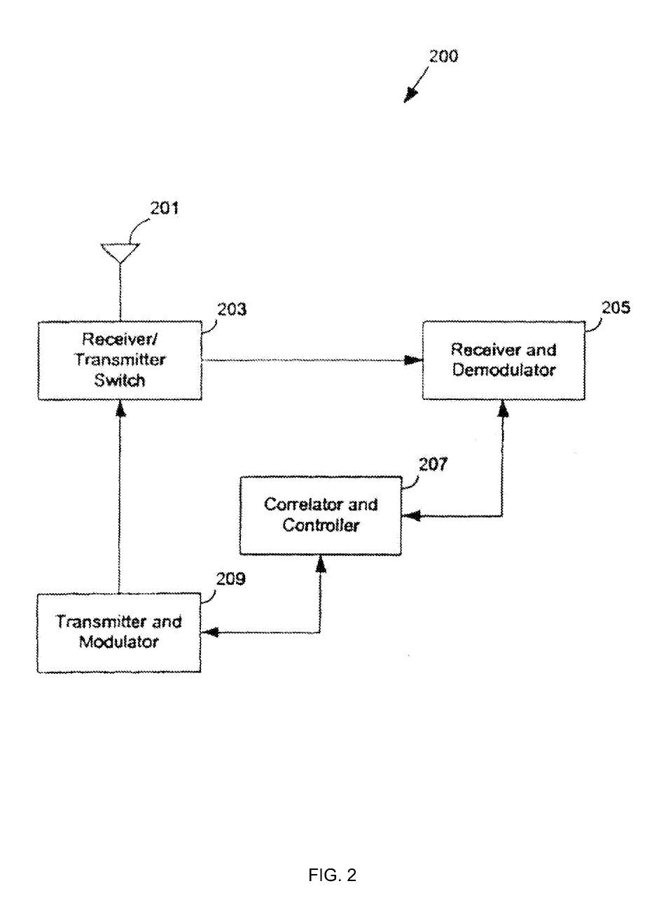

FIG. 2 illustrates an example of one implementation of a Tag that may be used with at least one embodiment of the present invention. The Tag 200 includes an antenna 201 that is coupled to the receiver and demodulator 205 and to the backscatter modulator 209. A correlator and controller unit 207 is coupled to the receiver and demodulator 205 and to the backscatter modulator 209. The particular example shown in FIG. 2 of a Tag may be used in various embodiments in which a memory for maintaining data between commands is maintained in the Tag and in which a bit by bit (or larger data chunk) correlation occurs in the Tag. The receiver and demodulator 205 receives signals through the antenna 201 and the switch 203, demodulates the signals, and provides these signals to the correlator and controller unit 207. Commands received by the receiver 205 are passed to the controller of the unit 207 in order to control the operation of the Tag. Data received by the receiver 205 is also passed to the control unit 207, and this data may include parameters for commands in the embodiments described below. The backscatter modulator 209, under control of the control unit 207, modulates the input impedance of the Tag corresponding to responses or other data through the antenna 201 to the Interrogator 101. It will be appreciated by those in the art that the modulation of the impedance of the chip to the antenna 201 will result in reflection changes at the interrogator which can be demodulated to extract the data sent by the Tag.

In one embodiment of the present invention, Tags are designed with properties such as a small Integrated Circuit (IC) area to permit low cost, small memory and non-precision timing requirements. In one embodiment, atomic transactions are used to minimize Tag state storage requirements. However, in other embodiments, other Tag designs can be used.

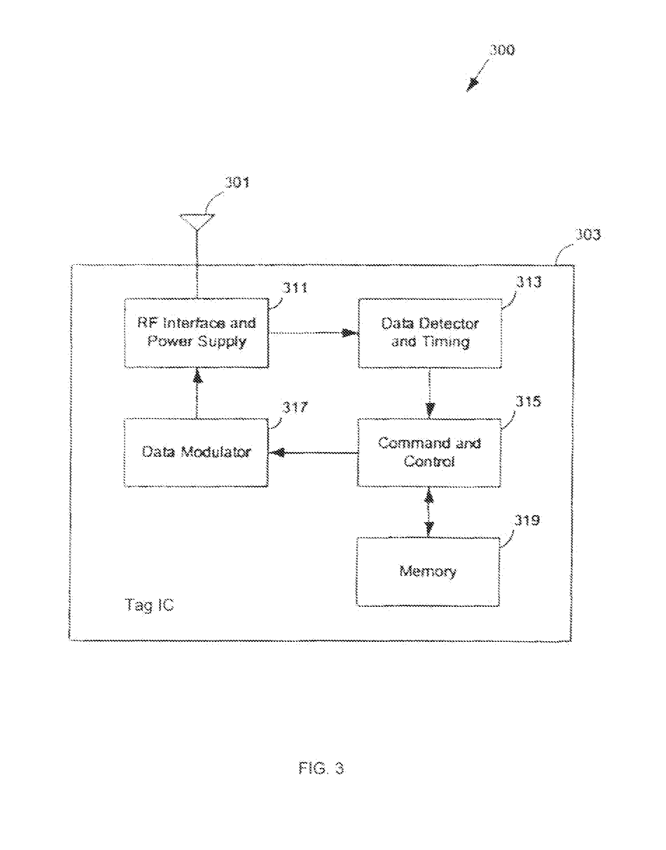

FIG. 3 illustrates an example of an RF Tag according to one embodiment of the present invention. In one embodiment, a VLC (Very Low Cost) Tag 300 includes an antenna 301 and an integrated circuit (IC) 303, connected together. The IC implements a command protocol and contains the Tag's identity code, which may be an electronic product code (EPC™) conforming to a Tag data standard such as the TAG Data Standard promulgated by the Tag Data Standard Working Group of EPCGlobal. The antenna 301 receives interrogation signals and reflects the interrogation signal back to the Interrogator 101 in response to a modulation signal created by the IC 303. The Tag IC 303 may comprise an RF interface and power supply 311, data detector and timing circuit 313, command and control 315, data modulator 317 and memory 319.

In one embodiment, the RF Interface and Power Supply 311 converts the RF energy into the DC power required for the Tag IC 303 to operate, and provides modulation information to the Data Detector and Timing circuit 313. Alternatively, power may be supplied by a battery or harvested power source. The data detector and timing block 313 de-modulates the reader signals and generates timing and data signals used by the control logic 315. The RF interface also provides a means of coupling the Tag modulation signals to the antenna for transmission to the Interrogator 101. The Data Detector and Timing circuit 313 de-modulates the Interrogator 101 signals and generates timing and data signals used by the command and control logic 315. The command and control logic 315 coordinates all of the functions of the Tag IC 303. The command and control logic 315 may include state logic to interpret data from the Interrogator 101, perform the required internal operations and determine if the Tag will respond to the Interrogator 101. The command and control logic 315 implements multiple Tag states and the communications protocol according to embodiments described below. The Tag memory 319 may contain the EPC™ code of the item tagged by a VLC Tag. The Tag memory 46 may contain a unique identification code or a non-unique identification code. The Tag memory may also contain a checksum that may be used for error detection. The data modulator 317 translates the binary Tag data into a signal that is then applied to the RF Interface 311 and then transmitted to the Interrogator 101. In one embodiment, the signal applied to the RF Interface 311 is transmitted via the antenna 301.

The design and implementation of the Tags can be characterized in layers. For example, a physical and environmental layer characterizes the mechanical, environmental, reliability and manufacturing aspects of a Tag; a radio frequency (RF) transport layer characterizes RF coupling between Readers and Tags; and a communication layer characterizes communications/data protocols between Readers and Tags. Various different implementations of Tags at different layers can be used with embodiments of the present invention. It is understood that the implementations of the Tags are not limited to the examples shown in this description. Different Tags or communication devices can use methods of the embodiments of the present invention for communication according to the needs of the target application.

In one embodiment of the invention, a Tag may be fabricated through a fluidic self-assembly process. For example, an integrated circuit may be fabricated with a plurality of other integrated circuits in a semiconductor wafer. The integrated circuit will include, if possible, all the necessary logic of a particular RF Tag, excluding the antenna 301. Thus, all the logic shown in the Tag 300 would be included on a single integrated circuit and fabricated with similar integrated circuits on a single semiconductor wafer. Each circuit would be programmed with a unique identification code and then the wafer would be processed to remove each integrated circuit from the wafer to create blocks that are suspended in a fluid.

The fluid is then dispersed over a substrate, such as a flexible substrate, to create separate RF Tags. Receptor regions in the substrate would receive at least one integrated circuit, which then can be connected with an antenna on the substrate to form an RF Tag.

As described above it is advantageous to couple an RFID IC to a lead frame with coil segments that function as a dual loop inductor and antenna.

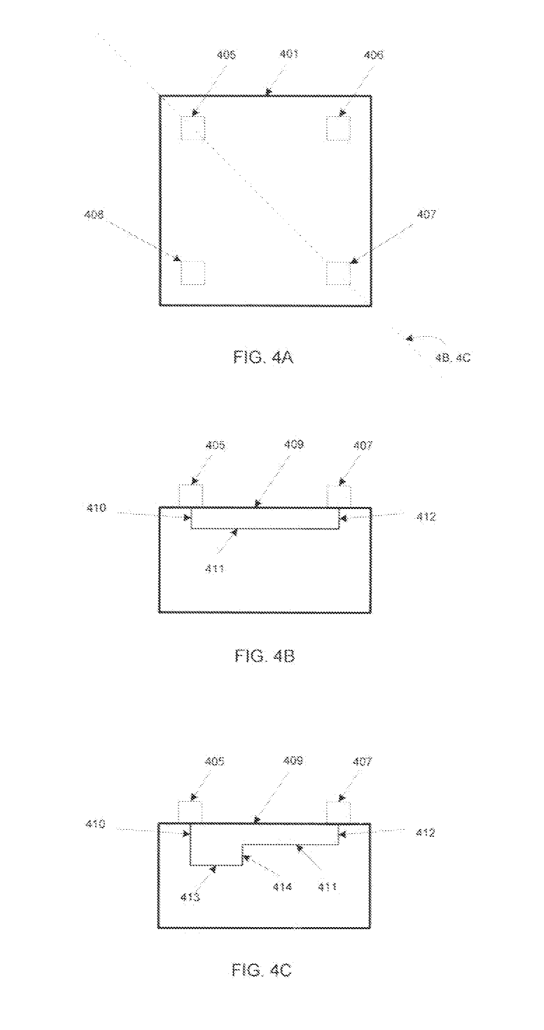

FIG. 4A illustrates an exemplary RFID IC 401 according to one embodiment of the present invention. The RFID IC 401 comprises of four terminals 405, 406, 407, and 408. In one embodiment, the RFID IC is in the shape of a square. It will be appreciated that the RFID IC may be in other shapes, e.g., rectangular.

Although FIG. 4A shows the four terminals 405, 406, 407, and 408 as being located in the four corners of the RFID IC, it will be appreciated that these terminals may be located anywhere on the RFID IC. In one embodiment, the terminals are equidistant with each other. In another embodiment, the terminals may not equidistant from each other. It will also be appreciated that in some embodiments, the RFID IC may have more or less than four terminals.

Terminals 405, 406, 407, and 408 are typically used for coupling the RFID IC to external electronic components. In one embodiment, such electronic component may be an antenna. In another embodiment, the external electronic component may be an inductor coil.

FIG. 4B illustrates the cross section side view of the exemplary RFID IC 401, along the dashed line 4B, 4C in FIG. 4A. Terminals 405 and 407 of the RFID IC 401 are coupled by a resistive interconnect comprising of segments 410, 411, and 412 which are within the integrated circuit (IC) that forms the RFID IC 401. In one embodiment, in order to achieve the connection between terminals 405 and 407 with the shortest length, the resistive interconnect 411 is a straight line from terminal 405 and 407. In another embodiment, it may not be possible for the resistive interconnect to be a straight line. In such an embodiment, the resistive interconnect may comprise of a combination of segments that are not aligned in a straight line (not shown in FIG. 4B) but have been formed in a masked lithography process in one or more layers of the IC. The masked lithography process can be part of a conventional semiconductor fabrication process that is used to manufacture the RFID IC.

In one embodiment, the RFID IC 401 has four terminals. In another embodiment, the RFID IC may have less than four terminals. Yet in another embodiment, the RFID IC 401 may have more than four terminals. In one embodiment, as disclosed above, only terminals 405 and 407 are connected by a resistive interconnect. However, in other embodiments, a resistive interconnect may be used to couple other terminals of the RFID IC 401.

FIG. 4B illustrates a resistive interconnect having one plane running in parallel with the RFID IC surface. In one embodiment, terminals 405 and 407 are coupled by the segments 410, 411, and 412 such that the resistive interconnection has a single plane 411 parallel to the surface 409 of the RFID IC 401.

FIG. 4C illustrates a resistive interconnect having two planes running in parallel with the RFID IC surface. As illustrated in FIG. 4C, terminals 405 and 407 may be connected by resistive interconnect segments 410, 411, 412, 413, and 414, resulting in a resistive interconnect having two planes 411 and 413 running in parallel with the surface 409 of the RFID IC 401. Yet in other embodiments, the terminals 405 and 407 may be connected by a configuration of segments resulting in an interconnect having three or more planes running in parallel with the surface 409 of the RFID IC 401 (not shown).

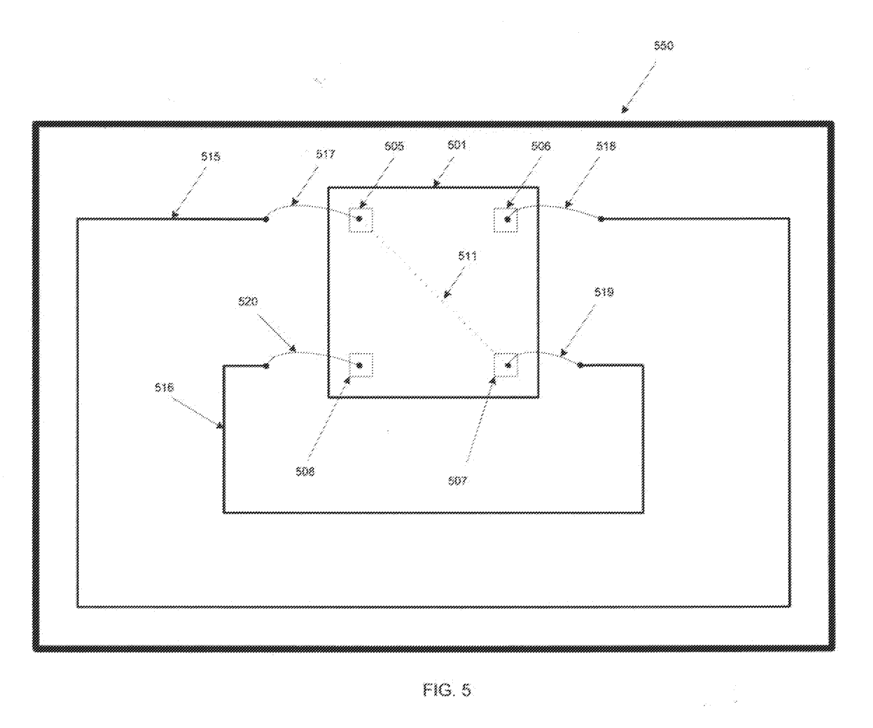

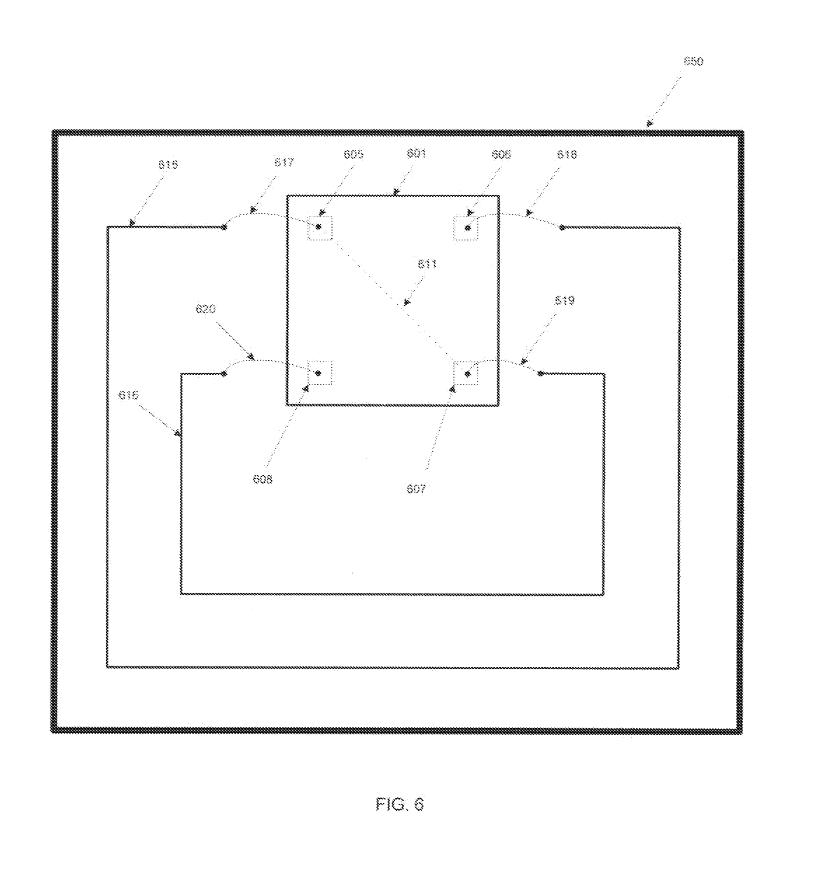

FIG. 5 illustrates an exemplary lead frame with coil segments that are coupled to the exemplary RFID IC of FIGS. 4A, 4B, and 4C, such that a dual loop coil is formed, with each end of the coil being coupled to a terminal of the RFID IC. In one embodiment, as illustrated in FIG. 5, a lead frame 550 comprises two coil segments 515 and 516. The embodiment further comprises four bonding wires 517, 518, 519, and 520. Bonding wire 517 couples the terminal 505 to the first end of the coil segment 515; bonding wire 518 couples the terminal 506 to second end of the coil segment 515; bonding wire 519 couples the terminal 507 to the first end of the coil segment 516; and, bonding wire 520 couples the terminal 508 to the second end of the coil segment 516. As discussed above, terminals 505 and 507 are connected by a resistive interconnect 511 within the RFID IC, which is illustrated in FIG. 5 as a dashed-line to indicate that it is below the surface of the RFID IC. In other words, the dashed line represents an interconnect within the RFID IC (such as RFID IC 401), and this interconnect is formed in one or more layers of the RFID IC. Thus, the configuration in FIG. 5 results in the RFID IC 501 being coupled to a single dual loop coil, with terminal 506 being coupled to the first end of the coil and the terminal 508 being coupled to the second end of the coil. RFID IC 501, like RFID IC 401, includes four terminals 505, 506, 507, and 508, which correspond to terminals 405, 406, 407, and 408, respectively, and terminals 505 and 507 are resistively coupled through the one or more layers of RFID IC 501 in the same manner that terminals 405 and 407 are coupled (through the one or more layers of the RFID IC 401). In one embodiment, these terminals can be bonding pads on the surface of the RFID ICs. In one embodiment, an antenna, such as a dipole antenna, can be coupled to one or more terminals of the RFID IC. FIG. 2 of U.S. Pat. No. 8,201,748 shows an example of such a dipole antenna coupled to two terminals of an RFID IC; U.S. Pat. No. 8,201,748 is incorporated herein by reference. In one embodiment, a dipole antenna is coupled to the RFID IC 501 by coupling one element of the dipole antenna to terminal 506 and by coupling another element of the dipole antenna to terminal 508; with this arrangement, the dual loop coil can act as an inductor that is coupled in parallel across the two elements of the dipole antenna. The other embodiments described herein, such as the embodiments shown in FIGS. 6, 7, 8, 9, 10A, and 10B, can also include an antenna coupled to one or more terminals of the RFID IC used in those embodiments.

In one embodiment, the RFID IC terminals are coupled to the coil segments by bonding wire. However, the present invention encompasses all types of conductive elements known to those skilled in the art, e.g., straps and ribbons.

In one embodiment, the dual loop coil acts as an inductor which tunes an antenna that is coupled to the RFID IC. In another embodiment, the dual loop coil may act as an inductor and an antenna for the RFID IC (such that a separate antenna is not used).

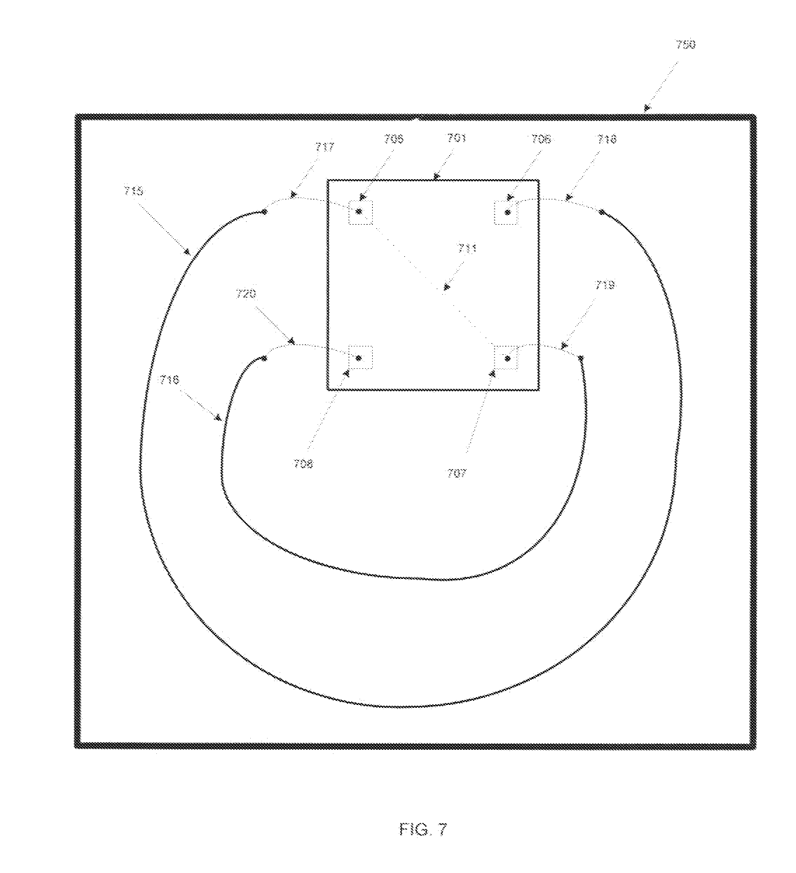

FIG. 6 illustrates an exemplary dual loop coil having the shape of a square. The dual loop coil may be formed in various shapes, e.g., square, rectangular, or circular. In FIG. 5, the dual loop coil is illustrated as having a rectangular shape. In another embodiment, as illustrated in FIG. 6, the dual loop coil may take on a square shape. Yet in another embodiment, as illustrated in FIG. 7, the coil segments may be formed such when bonding wires 717, 718, 719, and 720 are used to couple the terminals 705, 706, 707, and 708 to coil segments 717 and 716, the result is that a dual loop coil in the shape of a circle is coupled to the RFID IC.

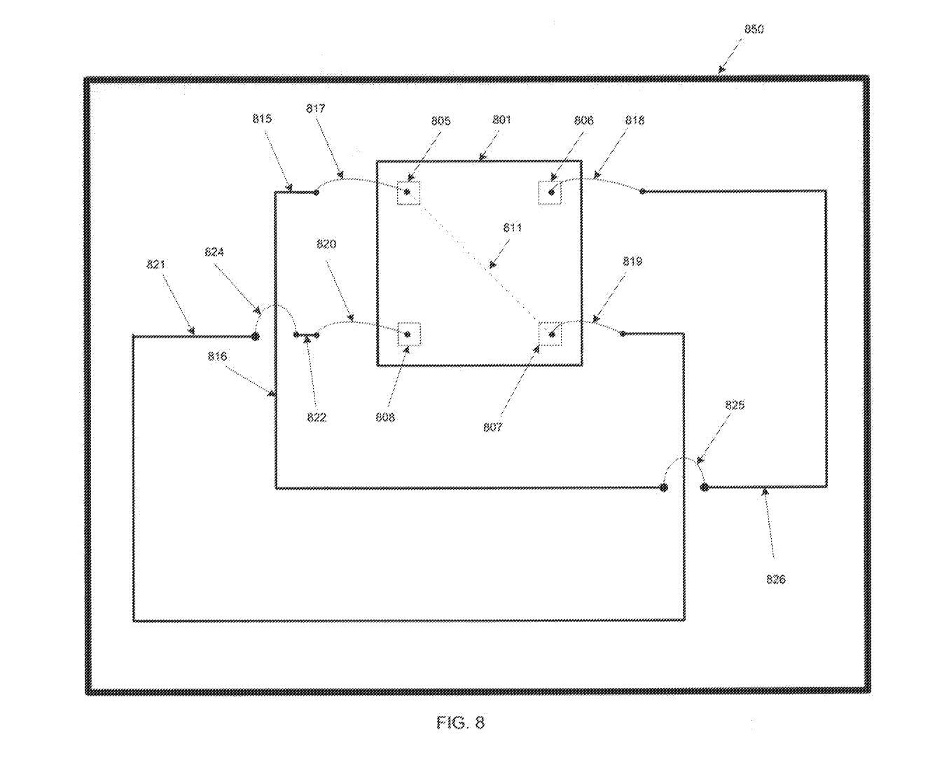

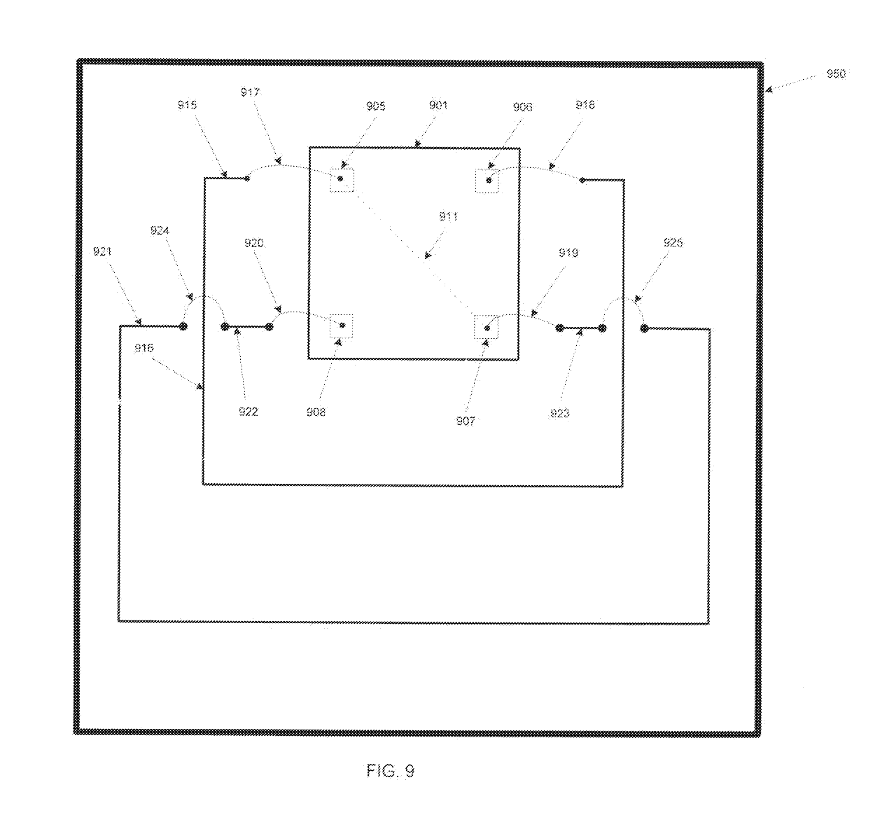

In one embodiment, the coil segments are formed on the lead frame such that the dual loop coil comprises two concentric coils without either coil segment overlapping the other, as illustrated in FIGS. 5, 6, and 7. In another embodiment, the dual loop coil may comprise of one or more coil segments overlapping another coil segment. For example, as illustrated in FIG. 8, coil segments 815, 821, 822, and 826 are formed on the lead frame 850. Bond wires 817, 818, 819, 820 are used for coupling the terminals 805, 806, 807, and 808 to the coil segments 815, 821, 822, and 826; in addition, bond wires 824 is used for coupling coil segment 821 to coil segment 822, and bond wire 825 is used for coupling coil segment 815 to coil segment 826. As a result, the dual loop coil consists of the two coils overlapping each other at two different locations. FIG. 9 illustrates another embodiment of the present invention where a dual loop coil consists of the coils overlapping each other. As illustrated in FIG. 9, coil segments 915, 921, 922, and 923 are formed on the lead frame 950. Bond wires 917, 918, 919, and 920 are used for coupling the terminals to the coil segments 915, 921, 922, and 926. Moreover, bond wire 924 is used for coupling coil segment 922 to coil segment 921, and bond wire 925 is used for coupling coil segment 921 to coil segment 923. Thus, the resulting dual loop coil consists of the coil overlapping each other at two locations, as illustrated in FIG. 9.

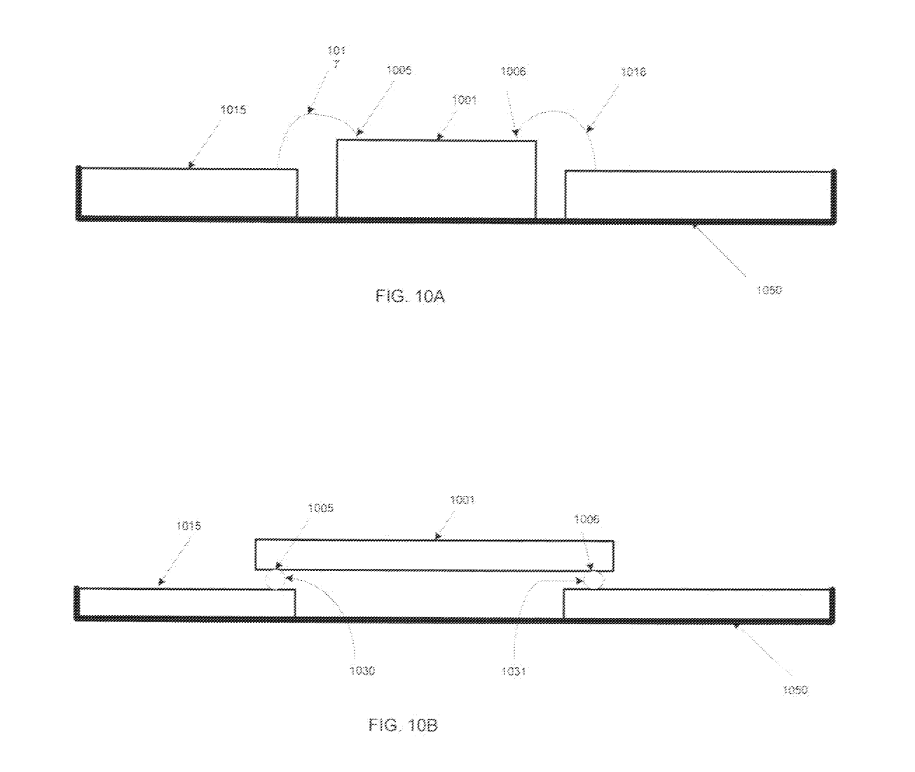

FIG. 10A is an illustration of a cross section side view of an RFID IC coupled to coil segments using bond wires as described above in the text relating to FIG. 5. RFID IC 1001 is mounted onto the lead frame 1050. As discussed above, the terminal 1005 is coupled to the first end of the coil segment 1015 via a bond wire 1017, and the terminal 1006 is coupled to the second end of the coil segment 1015 via bond wire 1018.

FIG. 10B is an illustration of a cross section side view of an RFID IC coupled to coil segments by a method known as flip chip, also commonly known as “controlled collapse chip connection.” Flip chip is a method that is used for interconnecting ICs such as the RFID IC 1001 to other electronic devices such as the coil segment 1015, by using solder balls 1030 and 1031 that have been deposited onto the terminals 1005 and 1006, respectively. The RFID IC is coupled to the coil segment via its terminals by flipping the RFID IC upside down, such that the solder balls make contact with the coil segments, and the solder balls are re-melted using commonly known methods such as ultrasonic or reflow solder process. Other methods of re-melting the solder balls known in the art are also contemplated by the present invention.

In one embodiment, the RFID IC, lead frame, and coil segments are encapsulated in an IC package, which may be made of ceramic, plastic, or other materials known in the art and an antenna can be coupled to one or more terminals on the RFID IC. The package type may be a dual-in-line (DIP) package, pin grid array (PGA) package, etc. The recitation of the package materials and types are for illustrative purposes only, and not intended to be interpreted as a limitation of the present invention.

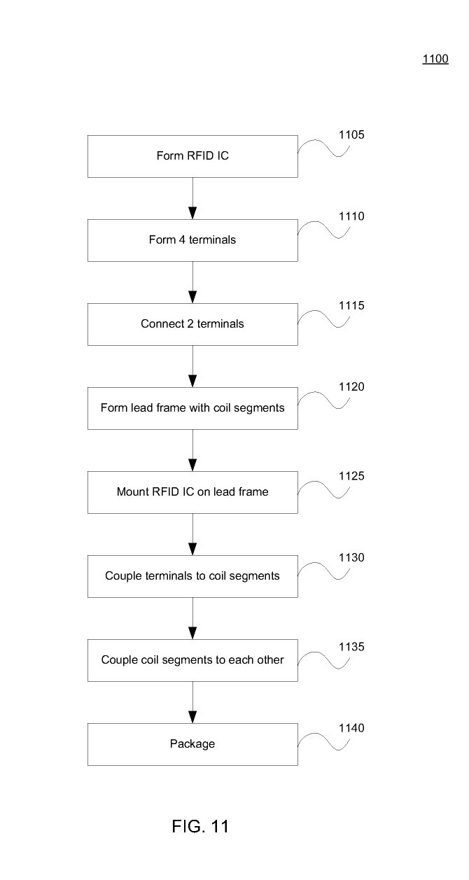

FIG. 11 illustrates a flowchart representation of one embodiment of manufacturing an RFID IC coupled to a dual loop coil. At block 1105, an RFID IC is formed.

At block 1110, four terminals are formed on the RFID IC, for the purpose of coupling the RFID IC to other electronic devices.

At block 1115, two of the RFID IC terminals are connected by a resistive interconnect as discussed above.

At block 1120, a lead frame is formed with multiple coil segments. The number of coil segments to be formed depends on the desired configuration of the resulting dual loop coil, as illustrated in FIGS. 5, 8, and 9. These configurations are for illustrative purposes only, and not intended to be a limitation on the present invention. Other configurations of the dual loop coil are contemplated by the present invention.

At block 1125, the RFID IC is mounted onto the lead frame.

At block 1130, the RFID IC terminals are coupled to the coil segments of the lead frame and an antenna can be coupled to one or more terminals on the RFID IC. As discussed above, this coupling can be achieved by use of bond wires, or other appropriate conductive elements. Alternatively, the coupling of the terminals to the coil segments may be achieved through the flip chip method disclosed above.

At block 1135, it may be necessary to couple the coil segments to each other, depending on the desired dual loop coil configuration. For example, the dual loop configuration as illustrated in FIG. 5 would not require any coupling of the coil segments to each other. However, the configuration as illustrated in FIGS. 8 and 9 would require bond wires to couple the coil segments to each other.

The foregoing embodiments of the invention may be described as a process that is usually depicted as a flowchart, a flow diagram, a structure diagram or a block diagram. Although a flowchart may describe the operations as a sequential process, many of the operations may be rearranged. The process is terminated when its operations are completed. A process may correspond to a method, a program, a procedure, etc.

What is claimed is:

1. An apparatus, comprising:
a radio frequency identification (RFID) integrated circuit (IC) having a first terminal, a second terminal, a third terminal, and a fourth terminal coupled to a surface of the RFID IC;
a lead frame having a first coil segment and a second coil segment, wherein a first end of the first coil segment is coupled to the first terminal, and a second end of the first coil segment is coupled to the second terminal;
wherein a first end of the second coil segment is coupled to the third terminal, and a second end of the second coil is coupled to the fourth terminal; and
a resistive interconnect having a first end coupled to the first terminal, and a second end coupled to the third terminal, the resistive interconnect being formed within one or more layers of the RFID IC.

2. The apparatus of claim 1, wherein the RFID IC is a passive RFID IC.

3. The apparatus of claim 1, wherein the first terminal is located at the upper left corner of the RFID IC, the second terminal is located at the upper right corner of the RFID IC, the third terminal is located at the lower right corner of the RFID IC, and the fourth terminal is located at the lower left corner of the RFID IC.

4. The apparatus of claim 1, wherein the first coil segment has a configuration selected from a group consisting of square, rectangle, and circle.

5. The apparatus of claim 1, wherein the second coil segment has a configuration selected from a group consisting of square, rectangle, and circle.

6. The apparatus of claim 1, wherein the resistive interconnect coupled to the first terminal and the third terminal is below the surface of the RFID IC.

7. The apparatus of claim 1, wherein the resistive interconnect coupled to the first terminal and the third terminal is on top of the surface of the RFID IC.

8. The apparatus of claim 2, wherein the first coil segment and the second coil segment function as an inductive tuning element for the RFID IC.

9. The apparatus of claim 8, wherein the first coil segment and the second coil segment also function as an antenna for the RFID IC.

10. The apparatus of claim 9, wherein the RFID IC, the first coil segment, the second coil segment, and the resistive interconnect are encapsulated in an IC package.

11. A method, comprising:
forming a radio frequency identification (RFID) integrated circuit (IC) having a first terminal, a second terminal, a third terminal, and a fourth terminal;
forming a lead frame having a first coil segment and a second coil segment, wherein a first end of the first coil segment is coupled to the first terminal, and a second end of the first coil segment is coupled to the second terminal; wherein a first end of the second coil segment is coupled to the third terminal, and a second end of the second coil is coupled to the fourth terminal; and
forming a resistive interconnect having a first end coupled to the first terminal, and a second end coupled to the third terminal, the resistive interconnect being formed within the RFID IC.

12. The method of claim 11, wherein the RFID IC is a passive RFID IC.

13. The method of claim 11, wherein the first terminal is located at the upper left corner of the RFID IC, the second terminal is located at the upper right corner of the RFID IC, the third terminal is located at the lower right corner of the RFID IC, and the fourth terminal is located at the lower left of the RFID IC.

14. The method of claim 11, wherein the first coil segment has a configuration selected from a group consisting of square, rectangle, and circle.

15. The method of claim 11, wherein the second coil segment has a configuration selected from a group consisting of square, rectangle, and circle.

16. The method of claim 11, where the resistive interconnect coupled to the first terminal and the third terminal is below the surface of the RFID IC.

17. The method of claim 11, wherein the resistive interconnect coupled to the first terminal and the third terminal is on top of the surface of the RFID IC.

18. The method of claim 12, wherein the first coil segment and the second coil segment function as an inductive tuning element for the RFID IC.

19. The method of claim 18, wherein the first coil segment and the second coil segment also function as an antenna for the RFID IC.

20. The method of claim 19, wherein the RFID IC, the first coil segment, the second coil segment, and the resistive interconnect are encapsulated in an IC package.
